(19) United States
(12) Patent Application Publication
(10) Pub. No.: US 2010/0244882 A1
(43) Pub. Date: Sep. 30, 2010

(54) Burn-In Test Method and System

(76) Inventor: Hong-Sok Choi, Gyeonggi-do (KR)

Correspondence Address: IP & T Law Firm PLC, 7700 Little River Turnpike, Suite 207, Annandale, VA, 22003, US

(21) Appl. No.: 12/486,268

(22) Filed: Jun. 17, 2009

(30) Foreign Application Priority Data
Mar. 30, 2009 (KR) 10-2009-0026909

(51) Int. Cl. G01R 31/26

(52) U.S. Cl. 324/765

(57) ABSTRACT

A method for performing a burn-in test of a metal wire for a signal transmission of a semiconductor device including driving a first terminal of the metal wire with a first voltage and forming a current path in the metal wire by driving a second terminal of the metal wire with a second voltage whose level is different from that of the first voltage.

### CROSS-REFERENCE TO RELATED APPLICATION

The present invention claims priority of Korean patent application number 10-2009-0026909, filed on Mar. 30, 2009, the disclosure of which is incorporated herein by reference in its entirety.

### BACKGROUND OF THE INVENTION

The present invention relates to a design technique for semiconductor device, and more particularly, to a burn-in test method for a metal wire of the semiconductor device.

The integrated circuits, the semiconductor devices, and the semiconductor memory devices are subjected to a burn-in test for detecting a fabrication error. The burn-in test operation is generally performed by applying a high operation voltage and repeating a certain internal operation in order to detect a time deterioration and defective part.

Particularly, a metal wire may include a weak connection point, whose width is extremely narrow, generated by the fabrication error. The weak connection point has relatively high resistance. Accordingly, when the signal is transmitted through the metal wire including the weak connection point, a signal delay is significantly increased; and even the metal wire can be damaged when the signal transmission is repeatedly performed.

FIG. 1 is a schematic diagram showing a conventional burn-in test scheme of a semiconductor device.

Referring to FIG. 1, the semiconductor device is a hierarchical word line decoder including a plurality of sub word line drive units 131A, 131B, 132A, 132B, 133A, and 133B, a first metal wire 120, and a plurality of second metal wires 121, 122, and 123, a first wire drive unit 110, and a plurality of second wire drive units 111, 112, and 113.

Each of the sub word line drive units 131A, 131B, 132A, 132B, 133A, and 133B drives corresponding one of sub word lines 151A, 151B, 152A, 152B, 153A, and 153B in response to a main word line selection signal MGW0B and a plurality of sub word line selection signals SGW0B, SGW1B, and SGW2B, respectively. The first metal wire 120, driven by a precharge voltage VPP and a ground voltage VSS, transmits the main word line selection signal MGW0B to the sub word line drive units 131A, 131B, 132A, 132B, 133A, and 133B. The second metal wires 121, 122, and 123, driven by the precharge voltage VPP and the ground voltage VSS, transmits the sub word line selection signals SGW0B, SGW1B, and SGW2B to the corresponding sub word line drive units 131A, 131B, 132A, 132B, 133A, and 133B. The first wire drive unit 110 drives the first metal wire 120 in response to a main decoding signal SEL_M0. Each of the second wire drive units 111, 112, and 113 drive corresponding second metal wires 121, 122, and 123 in response to a plurality of sub decoding signals SEL_S0, SEL_S1, and SEL_S2, respectively.

Herein, a plurality of memory cells MC are coupled to the sub word lines 151A, 151B, 152A, 152B, 153A, and 153B. The main decoding signal SEL_M0 and the sub decoding signals SEL_S0, SEL_S1, and SEL_S2 are generated by decoding a row address externally inputted.

Hereinafter, a detailed structure of the semiconductor device shown in FIG. 1 and an operation thereof will be described.

The first wire drive unit 110, coupled to the first metal wire 120, performs a pull-up/down operation to the first metal wire 120. The first wire drive unit 110 includes a first PMOS transistor MP0 and a first NMOS transistor MN0. The first PMOS transistor MP0 is arranged between a precharge voltage VPP terminal and a first output terminal N0 of the first wire drive unit 110. The first NMOS transistor MN0 is arranged between the first output terminal N0 and a ground voltage VSS terminal. Both of the first PMOS transistor MP0 and the first NMOS transistor MN0 receive the main decoding signal SEL_M0 through gates thereof.

Each of the second wire drive units 111, 112, and 113, coupled to the corresponding one of the second metal wires 121, 122, and 123, performs the pull-up/down operation to the corresponding second metal wires 121, 122, and 123, respectively. Each of the second wire drive units 111, 112, and 113 is implemented with a PMOS transistor and an NMOS transistors serially connected between the precharge voltage VPP terminal and the ground voltage VSS terminal and controlled by the corresponding sub decoding signals SEL_S0, SEL_S1, and SEL_S2.

Each of the sub word line drive units 131A, 131B, 132A, 132B, 133A, and 133B is implemented with a NOR gate receiving the main word line selection signal MGW0B and corresponding sub word line selection signals SGW0B, SGW0B, and SGW0B.

The operation of the semiconductor device shown in FIG. 1 in a normal operation mode is performed in the following way.

The main decoding signal SEL_M0 and the sub decoding signals SEL_S0, SEL_S1, and SEL_S2 have a logic low level during a precharge period. Thus, the PMOS transistors MP0 to MP3 included in the first wire drive unit 110 and the second wire drive units 111, 112, and 113 are turned on and, then, the first metal wire 120 and the second metal wires 121, 122, and 123 are precharged to the precharge voltage VPP.

The main decoding signal SEL_M0 has a logic high level during an active period and, accordingly, the first NMOS transistor MN0 is turned on. Therefore, the first metal wire 120 is driven as the ground voltage VSS. Meanwhile, it is presumed that the second sub decoding signal SEL_S1 has the logic high level; and the first and the third sub decoding signals SEL_S0 and SEL_S2 have the logic low level in the active period. Because the second sub decoding signal SEL_S1 has the logic high level, the NMOS transistor MN2 in the second wire drive unit 112 is turned on and, thus, the second metal wire 122 is driven as the ground voltage VSS. The PMOS transistors MP1 and MP3 are turned on in response to the first and the third sub decoding signals SEL_S0 and SEL_S2 of the logic high level; and the second metal wires 121 and 123 maintains precharge voltage VPP level.

In a burn-in test mode, the conventional semiconductor device operates as follows.

In order to detect the defects of the first and the second metal wires 120 to 123, a high operation voltage is applied to the semiconductor device; and a precharge operation and an active operation are repeatedly performed. Accordingly, the first and the second metal wires 120 to 123 get an electrical stress; and deterioration of the defective part of the first and the second metal wires 120 to 123 is accelerated. When the metal wires are damaged because of the deterioration, it is possible to detect a fabrication error of the semiconductor device. However, it takes a relatively long time to detect the error during a test operation; and it is difficult to sufficiently deteriorate the defective part of the metal wire by just applying the high operation voltage and repeating internal operations such as the precharge operation and the active operation.

### SUMMARY OF THE INVENTION

Embodiments of the present invention relate to a burn-in test method and system for a metal wire of the semiconductor device by forming a current path in the metal wire to thereby accelerate the deterioration of the defective part of the metal wire such as the weak connection point.

In accordance with an aspect of the present invention, there is provided a burn-in test method of metal wire for a signal transmission including driving a first terminal of the metal wire with a first voltage; and forming a current path in the metal wire by driving a second terminal of the metal wire with a second voltage whose level is different from that of the first voltage.

In accordance with another aspect of the present invention, there is provided a burn-in test system including a metal wire; a first drive unit, coupled to a first terminal of the metal wire, configured to precharge the metal wire with a precharge voltage during a precharge period and drive the metal wire with an active voltage during an active period; and a second drive unit, coupled to a second terminal of the metal wire, configured to provide the metal wire with an error detection voltage in a burn-in test mode.

### BRIEF DESCRIPTION OF THE DRAWINGS

FIG. 1 shows a schematic diagram showing a conventional semiconductor device.

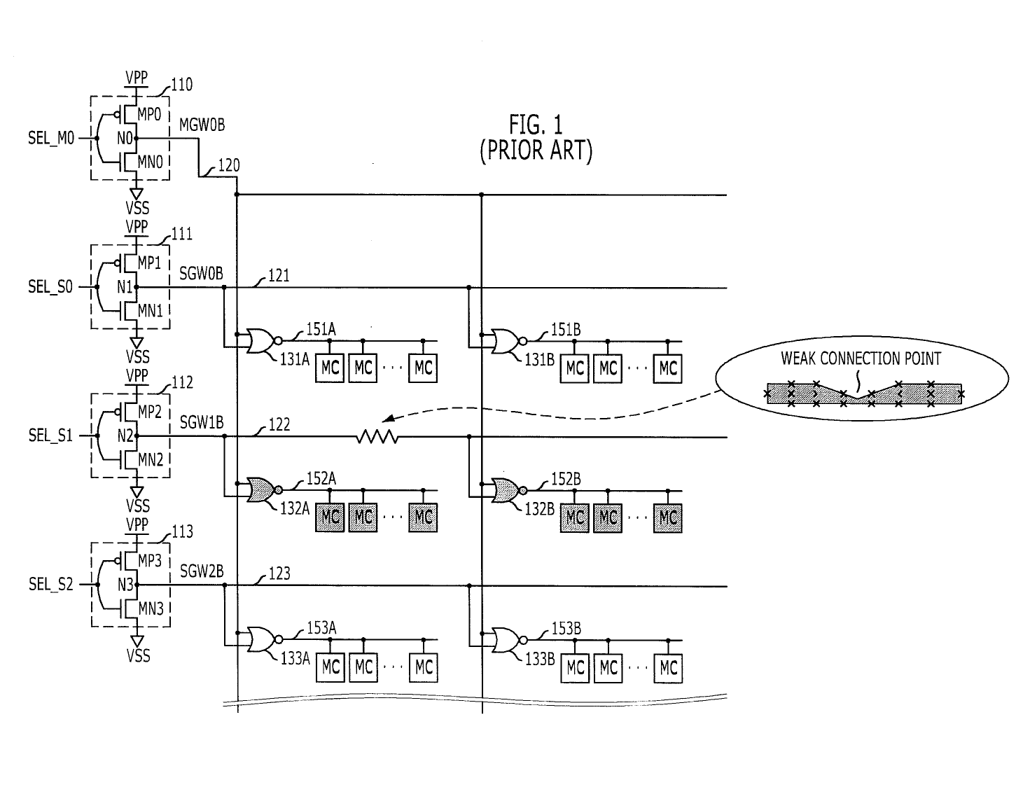

FIG. 2 shows a schematic diagram of an integrated circuit in accordance with an embodiment of the present invention.

FIG. 3 shows a schematic diagram of an integrated circuit in accordance with another embodiment of the present invention.

FIG. 4 shows a schematic diagram illustrating a semiconductor device in accordance with still another embodiment of the present invention.

FIG. 5 shows a schematic diagram illustrating a semiconductor device in accordance with a further embodiment of the present invention.

FIG. 6 shows a timing diagram illustrating an operation of the semiconductor device in accordance with the embodiment of the present invention shown in FIG. 4.

### DESCRIPTION OF SPECIFIC EMBODIMENTS

Other objects and advantages of the present invention can be understood by the following description, and become apparent with reference to the embodiments of the present invention.

Referring to the drawings, the same or like reference numerals represent the same or like constituent elements, although they appear in different embodiments or drawings of the present invention.

Generally, the signals have a logic high level and a logic low level which are represented as ‘1’ and ‘0’, respectively, according to the voltage level thereof. In addition, the signals also have a high impedance status Hi-Z.

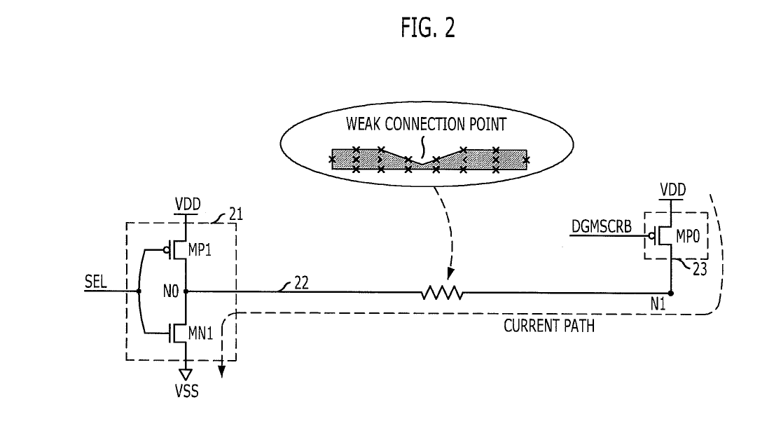

FIG. 2 is a schematic diagram of an integrated circuit in accordance with an embodiment of the present invention.

The integrated circuit includes a metal wire 22, and first and second drive units 21 and 23. The first drive unit 21, coupled a first terminal N0 of the metal wire 22, precharges the metal wire 22 as a power supply voltage VDD during a precharge period and drives the metal wire 22 as a ground voltage VSS during an active period. The second drive unit 23, coupled to a second terminal N1 of the metal wire 22, provides the metal wire 22 with the power supply voltage VDD during a burn-in test mode.

Hereinafter, the detailed structure and the operation of the integrated circuit shown in FIG. 2 will be described.

The first drive unit 21 includes a first pull-up drive unit MP1 and a first pull-down drive unit MN1. The first pull-up drive unit MP1 performs a pull-up drive operation to the metal wire 22. The first pull-down drive unit MN1 performs a pull-down drive operation to the metal wire 22. The first pull-up drive unit MP1 is implemented with a PMOS transistor arranged between a power supply voltage VDD terminal and the first terminal N0 and receives a selection signal SEL through its gate. The first pull-down drive unit MN1 is implemented with an NMOS transistor arranged between the first terminal N0 and a ground voltage VSS terminal and receives the selection signal SEL through its gate.

The second drive unit 23 includes a second pull-up drive unit MP0 for performing the pull-up drive operation to the metal wire 22. The second pull-up drive unit MP0 is implemented with a PMOS transistor for providing the metal wire 22 with the power supply voltage VDD in response to an error detection signal DGMSCRB.

In the normal operation mode, the selection signal SEL has the logic low level and, thus, the first pull-up drive unit MP1 in the first drive unit 21 is turned on to thereby precharge the metal wire 22 to the power supply voltage VDD during a precharge period. The selection signal SEL has the logic high level during an active period. The first pull-down drive unit MN1 in the first drive unit 21 is turned on in response to the selection signal SEL of the logic high level and drives the metal wire 22 as the ground voltage VSS. Meanwhile, the error detection signal DGMSCRB has the logic high level in the normal operation mode. Accordingly, the second pull-up drive unit MP0 in the second drive unit 23 is turned off; and the second drive unit does not provide the metal wire 22 with the power supply voltage VDD.

In the burn-in test mode, the error detection signal DGMSCRB has the logic low level. The second pull-up drive unit MP0 is turned on and, accordingly, the power supply voltage VDD is applied to the metal wire 22 through the second terminal N1. During the precharge period, the selection signal SEL has the logic low level; and the first pull-up drive unit MP1 is turned on in response to the selection signal SEL to thereby precharge the metal wire 22 to the power supply voltage VDD. Herein, the second drive unit 23 does not influence the precharge operation of the first drive unit 21 because the second drive unit 23 provides the power supply voltage VDD equivalent to the precharge voltage, i.e., the power supply voltage VDD. During the active period, the selection signal SEL has the logic high level; and the first pull-down drive unit MN1 is turned on in response to the selection signal SEL to drive the metal wire 22 as the ground voltage VSS. Meanwhile, the first and the second terminals N0 and N1 of the metal wire 22 are provided with the ground voltage VSS and the power supply voltage VDD, respectively, during the active period. This voltage difference between the first and the second terminals N0 and N1 of the metal wire 22 forms a current path in the metal wire 22.

As mentioned above, because of the fabrication error, the semiconductor device may include a metal wire having a weak connection point whose width is relatively narrow. The weak connection point has relatively high resistance. When the current path is formed in the metal wire 22, the weak connection point of high resistance is damaged due to an electrical stress. According to the embodiment of the present invention, it possible to efficiently detect a defective part of the metal wire 22 such as the weak connection part by inducing a current path in the metal wire 22.

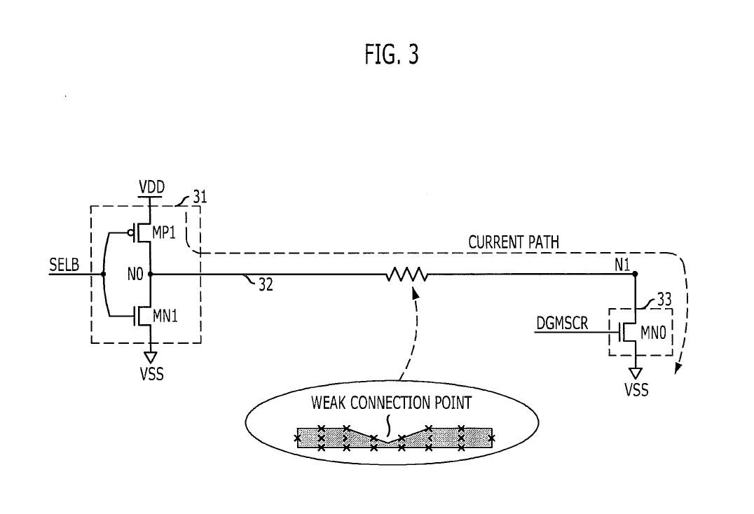

FIG. 3 is a schematic diagram of an integrated circuit in accordance with another embodiment of the present invention.

The integrated circuit includes a metal wire 32, and first and second drive units 31 and 33. The first drive unit 31, coupled a first terminal N0 of the metal wire 32, precharges the metal wire 32 to the ground voltage VSS during the precharge period in the normal operation mode and drives the metal wire 32 as the power supply voltage during the active period in the normal operation mode. The second drive unit 33, coupled to a second terminal N1 of the metal wire 32, provides the metal wire 32 with the ground voltage VSS during the burn-in test mode.

Hereinafter, the detailed structure and the operation of the integrated circuit shown in FIG. 3 will be described.

The first drive unit 31 includes a first pull-up drive unit MP1 and a first pull-down drive unit MN1. The first pull-up drive unit MP1 performs a pull-up drive operation to the metal wire 32. The first pull-down drive unit MN1 performs a pull-down drive operation to the metal wire 32. The first pull-up drive unit MP1 is implemented with a PMOS transistor arranged between the power supply voltage VDD terminal and a first terminal N0 and receives an inverted selection signal SELB through its gate. The first pull-down drive unit MN1 is implemented with an NMOS transistor arranged between the first terminal N0 and the ground voltage VSS terminal and receives the inverted selection signal SELB through its gate.

The second drive unit 33 includes a second pull-down drive unit MN0 for performing the pull-down drive operation to the metal wire 32. The second pull-down drive unit MN0 is implemented with an NMOS transistor for providing the metal wire 32 with the ground voltage VSS in response to an inverted error detection signal DGMSCR. Herein, the inverted selection signal SELB and the inverted error detection signal DGMSCR have the opposite phases with the selection signal SEL and the error detection signal DGMSCRB shown in FIG. 2, respectively.

In the normal operation mode, the inverted selection signal SELB has the logic high level during the precharge period and, thus, the first pull-down drive unit MN1 in the first drive unit 31 is turned on to thereby precharge the metal wire 32 to the ground voltage VSS. The inverted selection signal SELB has the logic low level during the active period. The first pull-up drive unit MP1 in the first drive unit 31 is turned on in response to the inverted selection signal SELB of the logic low level and drives the metal wire 32 as the power supply voltage VDD. Meanwhile, the inverted error detection signal DGMSCR has the logic low level in the normal operation mode. Accordingly, the second pull-down drive unit MN0 in the second drive unit 33 is turned off; and the second drive unit 33 does not provide the metal wire 32 with the ground voltage 33.

In the burn-in test mode, the inverted error detection signal DGMSCR has the logic high level. The second pull-down drive unit MN0 is turned on and, accordingly, the ground voltage VSS is applied to the metal wire 32 through the second terminal N1. During the precharge period, the inverted selection signal SELB has the logic high level; and the first pull-down drive unit MN1 is turned on in response to the inverted selection signal SELB to thereby precharge the metal wire 32 to the ground voltage VSS. Herein, the second drive unit 33 does not influence the precharge operation of the first drive unit 31 because the second drive unit 33 provides the ground voltage VSS equivalent to the precharge voltage, i.e., the ground voltage VSS. During the active period, the inverted selection signal SELB has the logic low level; and the first pull-up drive unit MP1 is turned on in response to the inverted selection signal SELB to drive the metal wire 32 as the power supply voltage VDD. Meanwhile, the first and the second terminals N0 and N1 of the metal wire 32 are provided with the power supply voltage VDD and the ground voltage VSS, respectively, during the active period. This voltage difference between the first and the second terminals N0 and N1 of the metal wire 32 forms a current path in the metal wire 32.

When the current path mentioned above is formed in the metal wire 32, the weak connection point of high resistance, which may exist in the metal wire 32, is damaged due to an electrical stress. As mentioned above, the embodiment of the present invention makes it possible to efficiently detect a defective part of the metal wire 22 such as the weak connection part by inducing a current path in the metal wire 32.

Consequently, the burn-in test operation of the above-mentioned embodiment performed by driving the metal wire and forming a current path to the metal wire. The burn-in test for the metal wire of the present embodiment can be applied to a metal word line connected to a plurality of memory cells and a metal wire for transmitting a word line selection signal required to a device having a hierarchical word line structure.

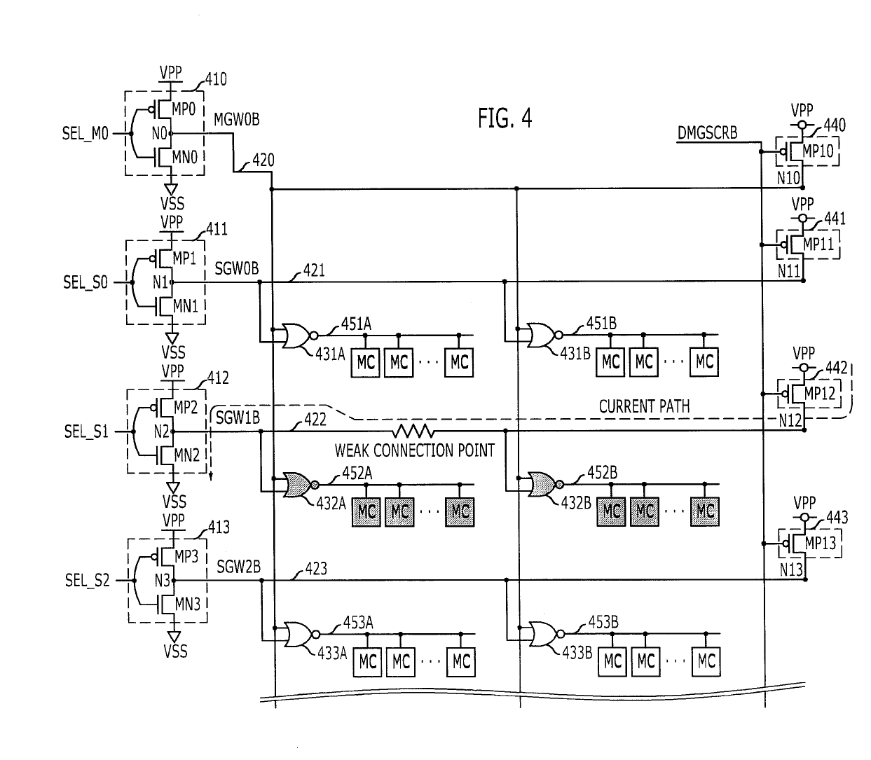

FIG. 4 is a schematic diagram illustrating a semiconductor device in accordance with still another embodiment of the present invention.

Referring to FIG. 4, the semiconductor device includes a hierarchical word line structure constituted with a main word line and a sub word line. The semiconductor device includes a plurality of sub word line drive units 431A, 431B, 432A, 432B, 433A, and 433B, a first metal wire 420, and a plurality of second metal wires 421, 422, and 423, and a plurality of current path drive units 440, 441, 442, and 443.

Each of the sub word line drive units 431A, 431B, 432A, 432B, 433A, and 433B drives corresponding one of sub word lines 451A, 451B, 452A, 452B, 453A, and 453B in response to a main word line selection signal MGW0B and a plurality of sub word line selection signals SGW0B, SGW1B, and SGW2B. The first metal wire 420, driven by a precharge voltage VPP and a ground voltage VSS, transmits the main word line selection signal MGW0B to the sub word line drive units 431A, 431B, 432A, 432B, 433A, and 433B. The second metal wires 421, 422, and 423, driven by the precharge voltage VPP and the ground voltage VSS, transmits the sub word line selection signals SGW0B, SGW1B, and SGW2B to the corresponding sub word line drive units 431A, 431B, 432A, 432B, 433A, and 433B. The current path drive units 440, 441, 442, and 443 forms a current path to the first metal wire 420 and the second metal wires 421, 422, and 423.

The semiconductor device may further include a first wire drive unit 410 and a plurality of second wire drive units 411, 412, and 413. The first wire drive unit 410 drives the first metal wire 420 in response to a main decoding signal SEL_M0. The second wire drive units 411, 412, and 413 drive corresponding second metal wires 421, 422, and 423 in response to a plurality of sub decoding signals SEL_S0, SEL_S1, and SEL_S2. Herein, a plurality of memory cells MC are coupled to the sub word lines 451A, 451B, 452A, 452B, 453A, and 453B. The main decoding signal SEL_M0 and the sub decoding signals SEL_S0, SEL_S1, and SEL_S2 are generated by decoding a row address externally inputted.

Hereinafter, a detailed structure of the semiconductor device shown in FIG. 4 and an operation thereof will be described.

The first wire drive unit 410, coupled to the first metal wire 420, performs a pull-up/down operation to the first metal wire 420. The first wire drive unit 410 includes a first PMOS transistor MP0 and a first NMOS transistor MN0. The first PMOS transistor MP0 is arranged between a precharge voltage VPP terminal and a first terminal N0 of the first metal wire 420. The first NMOS transistor MN0 is arranged between the first terminal N0 of the first metal wire 420 N0 and a ground voltage VSS terminal. Both the first PMOS transistor MP0 and the first NMOS transistor MN0 receive the main decoding signal SEL_M0 through gates thereof.

The first current path drive unit 440, coupled to a second terminal N10 of the first metal wire 420, provides the first metal wire 420 with the precharge voltage VPP in response to an error detection signal DGMSCRB. The first current path drive unit 440 includes a PMOS transistor MP10 connected between the precharge voltage terminal VPP and the second terminal N10 of the first metal wire 420 and receiving the error detection signal DGMSCRB through its gate.

Each of the second wire drive units 411, 412, and 413, coupled to the corresponding one of the second metal wires 421, 422, and 423, performs the pull-up/down operation to the corresponding second metal wires 421, 422, and 423. Each of the second wire drive units 411, 412, and 413 is implemented with a PMOS transistor and an NMOS transistor serially connected between the precharge voltage VPP terminal and the ground voltage VSS terminal and controlled by the corresponding sub decoding signals SEL_S0, SEL_S1, and SEL_S2.

The second to fourth current path drive units 441 to 443, coupled to corresponding second terminals N11, N12, and N13 of the second metal wires 421 to 423, respectively, provide the second metal wires 421 to 423 with the precharge voltage VPP in response to the error detection signal DGMSCRB. Each of the second to fourth current path drive units 441 to 443 includes a PMOS transistor MP11, MP12, or MP13. Each of PMOS transistors MP11, MP12, and MP13 is connected between the precharge voltage terminal VPP and the corresponding second terminals N11, N12, and N13 of the second metal wires 421 to 423 and receives the error detection signal DGMSCRB through its gate.

Each of the sub word line drive units 431A, 431B, 432A, 432B, 433A, and 433B is implemented with a NOR gate receiving the main word line selection signal MGW0B and corresponding one of the sub word line selection signals SGW0B, SGW1B, and SGW2B.

In a normal operation mode, the main decoding signal SEL_M0 and the sub decoding signals SEL_S0, SEL_S1, and SEL_S2 have the logic low level during a precharge period. Thus, the PMOS transistors MP0 to MP3 included in the first wire drive unit 410 and the second wire drive units 411, 412, and 413 are turned on and, then, the first metal wire 420 and the second metal wires 421, 422, and 423 are precharged to the precharge voltage VPP.

The main decoding signal SEL_M0 has a logic high level during an active period and, accordingly, the first NMOS transistor MN0 is turned on. Therefore, the first metal wire 420 is driven as the ground voltage VSS. Meanwhile, it is presumed that the second sub decoding signal SEL_S1 has the logic high level; and the first and the third sub decoding signals SEL_S0 and SEL_S2 have the logic low level. Because the second sub decoding signal SEL_S1 has the logic high level, the NMOS transistor MN2 in the second wire drive unit 412 is turned on and, thus, the second metal wire 422 is driven as the ground voltage VSS. The PMOS transistors MP1 and MP3 are turned on in response to the first and the third sub decoding signals SEL_S0 and SEL_S2 of the logic high level; and the second metal wires 421 and 423 maintains the precharge voltage VPP level.

The error detection signal DGMSCRB has the logic high level during the normal operation mode. Thus, the PMOS transistors MP10 to MP13 in the current path drive units 440, 441, 442, and 443 are turned off in response to the error detection signal DGMSCRB. The precharge voltage VPP is not provided to the first metal wire 420 and the second metal wires 421, 422, and 423 because the PMOS transistors MP10 to MP13 are turned off.

For the burn-in test mode, the error detection signal DGMSCRB has the logic low level. The current path drive units 440, 441, 442, and 443 provides the first metal wire 420 and the second metal wires 421, 422, and 423 with the precharge voltage VPP in response to the error detection signal DGMSCRB. In the precharge period, the main decoding signal SEL_M0 and the sub decoding signals SEL_S0, SEL_S1, and SEL_S2 have the logic low level. Thus, the PMOS transistors MP0 to MP3 included in the first wire drive unit 410 and the second wire drive units 411, 412, and 413 are turned on and, therefore, the first metal wire 420 and the second metal wires 421, 422, and 423 are precharged to the precharge voltage VPP. Herein, the current path drive units 440, 441, 442, and 443 has no influence on the precharge operation of the first wire drive unit 410 and the second wire drive units 411, 412, and 413 because the current path drive units 440, 441, 442, and 443 provides the precharge voltage VPP. During the active period, the main decoding signal SEL_M0 has the logic high level; and the first pull-down drive unit MN0 is turned on in response to the main decoding signal SEL_M0 to drive the first metal wire 420 as the ground voltage VSS. Meanwhile, it is presumed that the second sub decoding signal SEL_S1 has the logic high level; and the first and the third sub decoding signals SEL_S0 and SEL_S2 have the logic low level. Because the second sub decoding signal SEL_S1 has the logic high level, the NMOS transistor MN2 in the second wire drive unit 412 is turned on and, thus, the second metal wire 422 is driven to the ground voltage VSS. The PMOS transistors MP1 and MP3 are turned on in response to the first and the third sub decoding signals SEL_S0 and SEL_S2 of the logic high level; and the second metal wires 421 and 423 maintains precharge voltage VPP level.

Meanwhile, the current path drive units 440, 441, 442, and 443 provides the second terminals of the first and the second metal wires 420 to 423 with the precharge voltage VPP. Therefore, the first and the second terminals N0 and N10 of the first metal wire 420 are provided with the ground voltage VSS and the precharge voltage VPP, respectively, during the active period. The voltage difference between the first and the second terminals N0 and N10 of the first metal wire 420 forms a current path. Also, the first and the second terminals N2 and N12 of the second metal wire 422 are provided with the ground voltage VSS and the precharge voltage VPP, respectively, during the active period. The voltage difference between the first and the second terminals N2 and N12 of the second metal wire 422 forms a current path. Because the first and the second terminals of the second metal wires 421 and 423 have the equivalent voltage level as the precharge voltage VPP, the current path is not formed in the second metal wires 421 and 423.

When the current path mentioned above is formed in the metal wires 420 and 422, the weak connection point of high resistance, which may exist in the metal wires 420 and 422, is damaged due to an electrical stress. As mentioned above, the embodiment of the present invention makes it possible to efficiently detect a defective part of the metal wires 420 to 423 such as the weak connection part by inducing a current path in the metal wires 420 to 423.

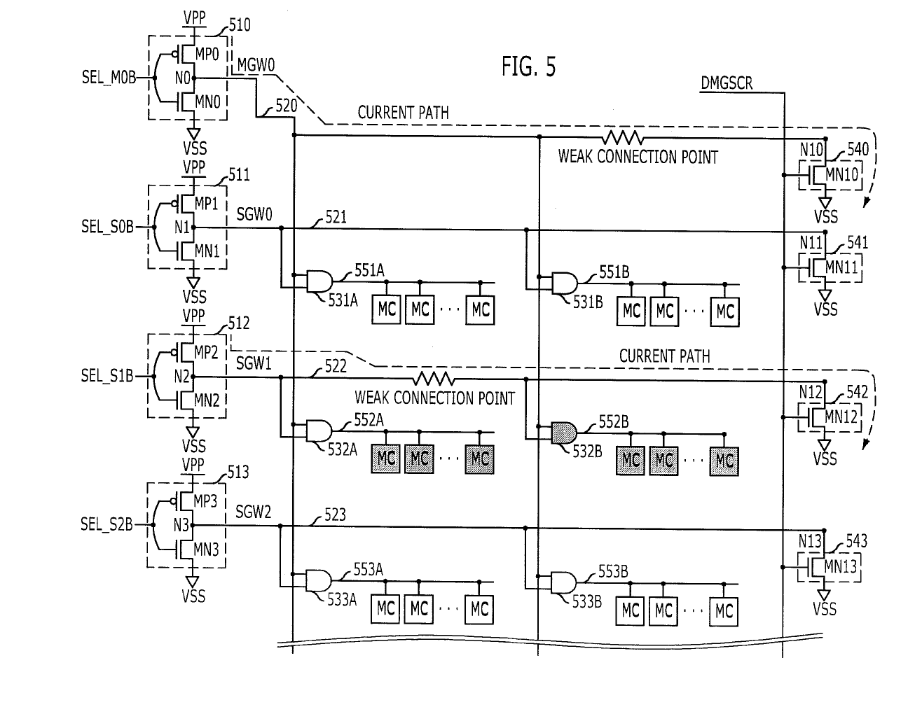

FIG. 5 is a schematic diagram illustrating a semiconductor device in accordance with a further embodiment of the present invention.

Referring to FIG. 5, the semiconductor device includes a hierarchical word line structure constituted with a main word line and a sub word line. The semiconductor device includes a plurality of sub word line drive units 531A, 531B, 532A, 532B, 533A, and 533B, a first metal wire 520, and a plurality of second metal wires 521, 522, and 523, and a plurality of current path drive units 540, 541, 542, and 543.

Each of the sub word line drive units 531A, 531B, 532A, 532B, 533A, and 533B drives corresponding one of sub word lines 551A, 551B, 552A, 552B, 553A, and 553B in response to an inverted main word line selection signal MGW0 and a plurality of inverted sub word line selection signals SGW0, SGW1, and SGW2. The first metal wire 520, driven by a precharge voltage VPP and a ground voltage VSS, transmits the inverted main word line selection signal MGW0 to the sub word line drive units 531A, 531B, 532A, 532B, 533A, and 533B. The second metal wires 521, 522, and 523, driven by the precharge voltage VPP and the ground voltage VSS, transmits the inverted sub word line selection signals SGW0, SGW1, and SGW2 to the corresponding sub word line drive units 531A, 531B, 532A, 532B, 533A, and 533B. The current path drive units 540, 541, 542, and 543 forms a current path to the first metal wire 520 and the second metal wires 521, 522, and 523 in response to the inverted error detection signal DGMSCR.

The semiconductor device may further include a first wire drive unit 510 and a plurality of second wire drive units 511, 512, and 513. The first wire drive unit 510 drives the first metal wire 520 in response to an inverted main decoding signal SEL_M0B. The second wire drive units 511, 512, and 513 drive corresponding second metal wires 521, 522, and 523 in response to a plurality of inverted sub decoding signals SEL_SOB, SEL_S1B, and SEL_S2B. Here, a plurality of memory cells MC are coupled to the sub word lines 551A, 551B, 552A, 552B, 553A, and 553B. The inverted main decoding signal SEL_M0B and the inverted sub decoding signals SEL_SOB, SEL_S1B, and SEL_S2B are generated by decoding a row address externally inputted.

The inverted main word line selection signal MGW0, the inverted sub word line selection signals SGW0, SGW1, and SGW2, the inverted main decoding signal SEL_M0B, the inverted sub decoding signals SEL_SOB, SEL_S1B, and SEL_SOB and the inverted error detection signal DGMSCR have the opposite phases from the main word line selection signal MGW0B, the sub word line selection signals SGW0B, SGW1B, and SGW0B, the main decoding signal SEL_M0, the sub decoding signals SEL_S0, SEL_S1, and SEL_S2 and error detection signal DGMSCRB, respectively.

Hereinafter, a detailed structure of the semiconductor device shown in FIG. 5 and an operation thereof will be described.

The first wire drive unit 510, coupled to the first metal wire 520, performs the pull-up/down operation to the first metal wire 520. The first wire drive unit 510 includes a first PMOS transistor MP0 and a first NMOS transistor MN0. The first PMOS transistor MP0 is arranged between the precharge voltage VPP terminal and a first terminal N0 of the first metal wire 520. The first NMOS transistor MN0 is arranged between the first terminal N0 of the first metal wire 520 N0 and the ground voltage VSS terminal. Both the first PMOS transistor MP0 and the first NMOS transistor MN0 receive the inverted main decoding signal SEL_M0B through gates thereof.

The first current path drive unit 540, coupled to a second terminal N10 of the first metal wire 520, provides the first metal wire 520 with the ground voltage VSS in response to an inverted error detection signal DGMSCR. The first current path drive unit 540 includes an NMOS transistor MN10 connected between the ground voltage VSS terminal and the second terminal N10 of the first metal wire 520 and receiving the inverted error detection signal DGMSCR through its gate.

Each of the second wire drive units 511, 512, and 513, coupled to the corresponding one of the second metal wires 521, 522, and 523, performs the pull-up/down operation to the corresponding second metal wires 521, 522, and 523. Each of the second wire drive units 511, 512, and 513 is implemented with a PMOS transistor and an NMOS transistor serially connected between the precharge voltage VPP terminal and the ground voltage VSS terminal and controlled by the corresponding inverted sub decoding signals SEL_SOB, SEL_S1B, and SEL_SOB.

The second to fourth current path drive units 541 to 543, coupled to corresponding second terminals N11, N12, and N13 of the second metal wires 521 to 523, respectively, provide the second metal wires 521 to 523 with the ground voltage VSS in response to the inverted error detection signal DGMSCR. Each of the second to fourth current path drive units 541 to 543 respectively includes NMOS transistors MN11, MN12, or MN13. Each of NMOS transistors MN11, MN12, or MN13 is connected between the ground voltage VSS and the corresponding second terminals N11, N12, and N13 of the second metal wires 521 to 523 and receives the inverted error detection signal DGMSCR through its gate.

Each of the 531A, 531B, 532A, 532B, 533A, and 533B is implemented with a NOR gate receiving the inverted main word line selection signal MGW0 and corresponding one of the inverted sub word line selection signals SGW0, SGW1, and SGW2.

In a normal operation mode, the inverted main decoding signal SEL_M0B and the inverted sub decoding signals SEL_SOB, SEL_S1B, and SEL_SOB have the logic high level during the precharge period. Thus, the NMOS transistors MN0 to MN3 included in the first wire drive unit 510 and the second wire drive units 511, 512, and 513 are turned on and, then, the first metal wire 520 and the second metal wires 521, 522, and 523 are driven as the ground voltage VSS.

The inverted main decoding signal SEL_M0B has the logic low level during the active period and, accordingly, the first PMOS transistor NP0 is turned on. Therefore, the first metal wire 520 is driven at the precharge voltage VPP. Meanwhile, it is presumed that the second inverted sub decoding signal SEL_S1B has the logic low level; and the first and the third inverted sub decoding signals SEL_SOB and SEL_S2B have the logic high level. Because the second inverted sub decoding signal SEL_S1B has the logic low level, the PMOS transistor MP2 in the second wire drive unit 512 is turned on and, thus, the second metal wire 522 is driven to the precharge voltage VPP. The NMOS transistors MN1 and MN3 are turned on in response to the first and the third inverted sub decoding signals SEL_SOB and SEL_S2B of the logic high level; and the second metal wires 521 and 523 maintains ground voltage VSS level.

The inverted error detection signal DGMSCR has the logic low level during the normal operation mode. Thus, the NMOS transistors MN10 to MN13 in the current path drive units 540, 541, 542, and 543 are turned off in response to the inverted error detection signal DGMSCR. The ground voltage VSS is not provided to the first metal wire 520 and the second metal wires 521, 522, and 523 because the NMOS transistors MN10 to MN13 are turned off.

For the burn-in test mode, the inverted error detection signal DGMSCR has the logic high level. The current path drive units 540, 541, 542, and 543 provides the first metal wire 520 and the second metal wires 521, 522, and 523 with the ground voltage VSS in response to the inverted error detection signal DGMSCR. In the precharge period, the inverted main decoding signal SEL_M0B and the inverted sub decoding signals SEL_SOB, SEL_S1B, and SEL_S2B have the logic high level. Thus, the NMOS transistors MN0 to MN3 included in the first wire drive unit 510 and the second wire drive units 511, 512, and 513 are turned on and, therefore, the first metal wire 520 and the second metal wires 521, 522, and 523 are precharged to the ground voltage VSS. Herein, the current path drive units 540, 541, 542, and 543 do not influence the precharge operation of the first wire drive unit 510 and the second wire drive units 511, 512, and 513 because the current path drive units 540, 541, 542, and 543 provides the ground voltage VSS.

During the active period, the inverted main decoding signal SEL_M0B has the logic low level; and the first pull-up drive unit MP0 is turned on in response to the inverted main decoding signal SEL_M0B to drive the first metal wire 520 to the precharge voltage VPP. Meanwhile, it is presumed that the second inverted sub decoding signal SEL_S1B has the logic low level; and the first and the third inverted sub decoding signals SEL_SOB and SEL_S2B have the logic high level. Because the second inverted sub decoding signal SEL_S1B has the logic low level, the PMOS transistor MP2 in the second wire drive unit 512 is turned on and, thus, the second metal wire 522 is driven to the precharge voltage VPP. The NMOS transistors MN1 and MN3 are turned on in response to the first and the third inverted sub decoding signals SEL_SOB and SEL_S2B of the logic high level; and the second metal wires 521 and 523 maintain the ground voltage VSS level.

Meanwhile, the current path drive units 540, 541, 542, and 543 provides the second terminals of the first and the second metal wires 520 to 523 with the ground voltage VSS. Therefore, the first and the second terminals N0 and N10 of the first metal wire 520 are provided with the precharge voltage VPP and the ground voltage VSS, respectively, during the active period. The voltage difference between the first and the second terminals N0 and N10 of the first metal wire 520 forms a current path. Also, the first and the second terminals N2 and N12 of the second metal wire 522 are provided with the precharge voltage VPP and the ground voltage VSS, respectively, during the active period. The voltage difference between the first and the second terminals N2 and N12 of the second metal wire 522 forms a current path. Because the first and the second terminals of the second metal wires 521 and 523 have the equivalent voltage level as the ground voltage VSS, the current path is not established in the second metal wires 521 and 523.

When the current path mentioned above is formed in the metal wires 520 and 522, the weak connection point of high resistance, which may exist in the metal wires 520 and 522, is damaged due to an electrical stress. As mentioned above, the embodiment of the present invention makes it possible to efficiently detect a defective part of the metal wires 520 to 523 such as the weak connection part by inducing a current path in the metal wires 520 to 523.

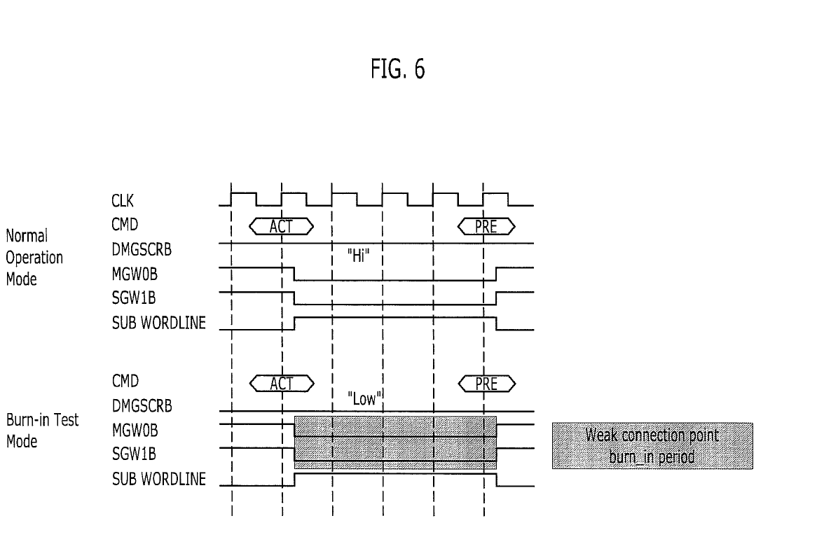

FIG. 6 is a timing diagram illustrating an operation of the semiconductor device in accordance with the embodiment of the present invention shown in FIG. 4.

The semiconductor device drives the selected sub word line as the logic high level in response to an active command ACT. In this case, it is presumed that the semiconductor device selects the sub word lines 452A and 452B. The sub word line drive units 432A and 432B drives the selected sub word line, i.e., the sub word lines 452A and 452B, in response to the main word line selection signal MGW0B and the sub word line selection signal SGW1B of the logic low level. In the normal operation mode, the error detection signal DGMSCRB is inactivated as the logic high level. Thus, the semiconductor device performs internal operations such as the precharge operation and the active operation in the normal operation mode. Meanwhile, the error detection signal DGMSCRB is activated as the logic low level in the burn-in test mode. Therefore, the current path drive unit 442 provides the error detection voltage, i.e., the precharge voltage VPP, to the second metal wire 422 in response to the sub word line selection signal SGW1B of the logic low level. The voltage difference between the first and the second terminals N2 and N12 of the second metal wire 422 forms a current path. When the current path mentioned above is formed in the metal wire 422, the weak connection point of high resistance, which may exist in the metal wire 422, is damaged due to an electrical stress. As mentioned above, the embodiment of the present invention makes it possible to efficiently detect a defective part of the metal wires such as the weak connection part by inducing a current path in the metal wires.

Embodiments of the present invention relate to a method for a burn-in test method for a metal wire of the semiconductor device by forming a current path in the metal wire to thereby accelerate the deterioration of the defective part of the metal wire such as the weak connection point.

While the present invention has been described with respect to the specific embodiments, it will be apparent to those skilled in the art that various changes and modifications may be made without departing from the spirit and scope of the invention as defined in the following claims.

For example, although the first metal wire and the second metal wires are simultaneously provided with the error detection voltage in the abovementioned embodiments, it is also possible to modify the structure of the semiconductor device to independently provide the first metal wire and the second metal wires with the error detection voltage in other embodiments. Further, the error detection signal can be generated by using the mode register set code or the test code externally inputted. The error detection signal also can be an external test signal externally inputted.

What is claimed is:

1. A method for performing a burn-in test of a metal wire for a signal transmission of a semiconductor device, comprising:
driving a first terminal of the metal wire with a first voltage; and
forming a current path in the metal wire by driving a second terminal of the metal wire with a second voltage whose level is different from that of the first voltage.

2. The method of claim 1, wherein the metal wire is a word line coupled to a plurality of memory cells.

3. The method of claim 1, wherein the metal wire is configured to transmit a main word line selection signal.

4. The method of claim 1, wherein the metal wire is configured to transmit a sub word line selection signal.

5. A system for performing a burn-in test of a semiconductor memory device, comprising:
a metal wire;
a first drive unit, coupled to a first terminal of the metal wire, configured to precharge the metal wire with a precharge voltage during a precharge period and drive the metal wire with an active voltage during an active period; and
a second drive unit, coupled to a second terminal of the metal wire, configured to provide the metal wire with an error detection voltage in a burn-in test mode.

6. The system of claim 5, wherein the metal wire is a word line coupled to a plurality of memory cells.

7. The system of claim 5, wherein the metal wire is to transmit a main word line selection signal.

8. The system of claim 5, wherein the metal wire is to transmit a sub word line selection signal.

9. The system of claim 5, wherein the error detection voltage has the equivalent voltage level with the precharge voltage.

10. The system of claim 5, wherein the first drive unit includes:
a pull-up drive unit configured to perform a pull-up drive operation on the metal wire in response to a selection signal; and
a pull-down drive unit configured to perform a pull-down drive operation on the metal wire in response to the selection signal.

11. The system of claim 10, wherein the pull-up drive unit includes a PMOS transistor coupled between a power supply voltage terminal and an output terminal and controlled by the selection signal.

12. The system of claim 11, wherein the pull-down drive unit includes an NMOS transistor coupled between the output terminal and a ground voltage terminal and controlled by the selection signal.

13. The system of claim 5, wherein the second drive unit includes a pull-up drive unit configured to perform a pull-up drive operation to the metal wire in response to an error detection signal.

14. The system of claim 13, wherein the pull-up drive unit includes a transistor configured to provide the metal wire with a power supply voltage in response to the error detection signal.

15. The system of claim 14, wherein the error detection signal is generated by using a mode register set code.

16. The system of claim 14, wherein the error detection signal is generated by using a test code externally inputted.

17. The system of claim 14, wherein the error detection signal is an external test signal externally inputted.

18. The system of claim 5, wherein the second drive unit includes a pull-down drive unit configured to perform a pull-down drive operation to the metal wire in response to an error detection signal.

19. The system of claim 18, wherein the pull-down drive unit includes a transistor configured to provide the metal wire with a ground voltage in response to the error detection signal.

20. The system of claim 19, wherein the error detection signal is generated by using a mode register set code.

21. The system of claim 19, wherein the error detection signal is generated by using a test code externally inputted.

22. The system of claim 19, wherein the error detection signal is an external test signal externally inputted.
